(19) United States
(12) Patent Application Publication
(10) Pub. No.: US 2006/0211248 A1
(43) Pub. Date: Sep. 21, 2006

(54) Purifier for chemical reactor

(76) Inventors: Paul D. Brabant, E. Kachina Trail, AZ (US); Paul Jacobson, Phoenix, AZ (US); Keith D. Weeks, Gilbert, AZ (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/362,461

(22) Filed: Feb. 24, 2006

Related U.S. Application Data
(60) Provisional application No. 60/656,729, filed on Feb. 25, 2005.

(51) Int. Cl. H01L 21/306; H01L 21/302; C23F 1/00

(52) U.S. Cl. 438/689; 156/345.1

(57) ABSTRACT

A method for purifying a gas stream in a semiconductor process system comprises cooling impurities in the gas stream. The gas stream may comprise an HCl gas having a moisture content. The moisture contacts a cold element onto which the moisture can condense.

### PRIORITY INFORMATION

This application claims the benefit of U.S. Provisional Application No. 60/656,729, filed Feb. 25, 2005, the entirety of which is hereby incorporated by reference.

### BACKGROUND OF THE INVENTION

1. Field of the Invention

The present invention relates to chemical processes. More particularly, the invention relates to purifying a reactant in a chemical process.

2. Description of the Related Art

High purity gases are often used for the manufacture of semiconductor devices, laboratory research, mass spectrometer instruments and other industries and applications. For example, with respect to semiconductor manufacturing processes, high purity HCl is used in many epitaxial processes. However, even the best grades of HCl can have moisture concentrations in the range of 1 ppm to 30 ppm. Such concentrations of moisture can be detrimental to film growth especially in lower temperature epitaxial processes.

There are several devices for removing moisture or other impurities from a gas flow. Most of these devices use solid materials to which the molecules of the impurities in the gas stream can bond by interacting with the solid materials according to a variety of mechanisms. For example, with respect to HCl gas, metallorganic resin purifiers are used to remove moisture from a HCl gas stream. The moisture bonds with the resin which must be replaced once it becomes saturated. While useful, such purifiers are typically limited to removing moisture only down to about 100 ppb levels in optimum conditions. In addition, if the moisture level in the HCl gas becomes higher (e.g., greater than 1 ppm) the resin purifier can quickly become overwhelmed and can no longer remove moisture to the optimum levels (e.g., below 100 ppb). In addition, these purifiers, once saturated, require a very long recovery time (e.g., 6-12 hours). Another drawback to these purifiers is that there is typically no signal indicating when the purifier becomes saturated and no longer effective. As such, the deposition process is typically compromised before any indication of saturation is determined.

Therefore, a need exists for an improved purifier, especially a purifier capable of removing moisture from a gas stream such as, for example, a gas stream of HCl.

### SUMMARY OF THE INVENTION

One embodiment of the present invention involves a method of forming an integrated circuit. The method comprises supplying a HCl gas stream to a conduit system; cooling impurities in the HCl gas stream to remove the impurities from the HCl gas; and supplying the purified HCl gas stream to a process chamber. In one arrangement, the impurity is cooled by passing the HCl gas stream through a cooled element and the cooled element is regenerated when the pressure drop across the cooled element exceeds a specified limit.

Another embodiment of the present invention involves an apparatus for forming a semiconductor device. The apparatus includes a source of HCl gas and a gas conduit system that connects the source of HCl gas to the reaction chamber. A purifier is positioned within the gas conduit system for purifying a HCl gas stream. The purifier includes a cooling element configured to reduce the temperature of impurities in the HCl gas stream.

It should also be noted that all of these embodiments are intended to be within the scope of the invention herein disclosed. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

In the following, the invention will be described in greater detail with the help of exemplifying embodiments illustrated in the appended drawings, in which like reference numbers are employed for similar features in different embodiments and, in which

FIG. 1 is a schematic illustration of an apparatus for supplying a reactant to reactor according to an embodiment of the present invention;

FIG. 2 is a schematic illustration of an apparatus for purifying a reactant stream according to an embodiment of the present invention;

FIG. 3 is a schematic sectional view of an exemplary single-substrate reaction chamber for use with preferred embodiments of the invention; and

FIG. 4 is a gas flow schematic, illustrating exemplary reactant and inert gas sources in accordance with preferred embodiments of the invention.

### DETAILED DESCRIPTION OF THE PREFERRED EMBODIMENTS

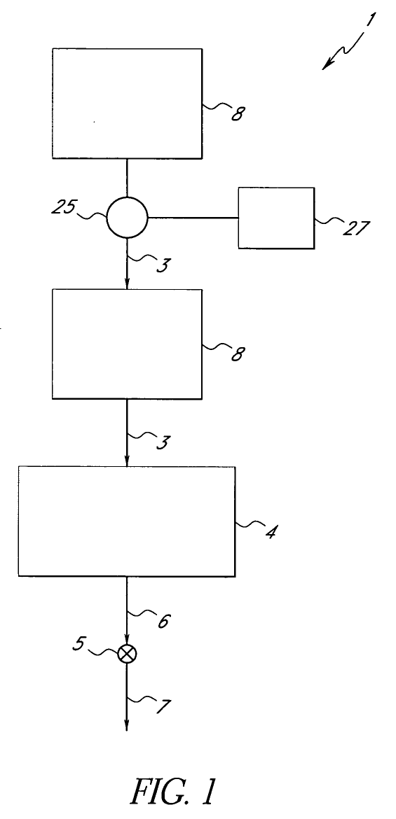

FIG. 1 is a schematic illustration of a semiconductor processing system 1. The system 1 comprises a reactant source 2 that is connected through a reactant conduit 3 to a semiconductor processing chamber 4. The reactant can be present in the reactant source 2 as a compressed gas or as a vapor phase reactant in communication with a part of the reactant that is present in liquid or solid phase, provided that the vapor pressure of the reactant is sufficiently high to transport the reactant to the reaction chamber 4. If the vapor pressure is not sufficiently high to transport the reactant to the reaction chamber 4, a carrier gas (not shown) and/or heating system (not shown) may be used. Gases are removed from the processing chamber 4 by a vacuum pump 5 via an outlet conduit 6 and exhausted through a pump exhaust 7.

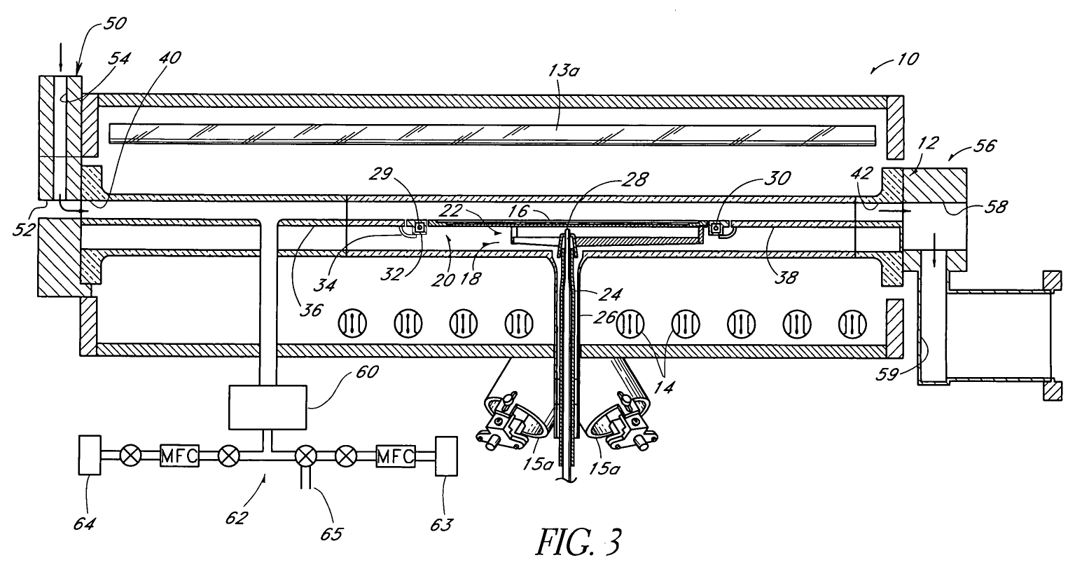

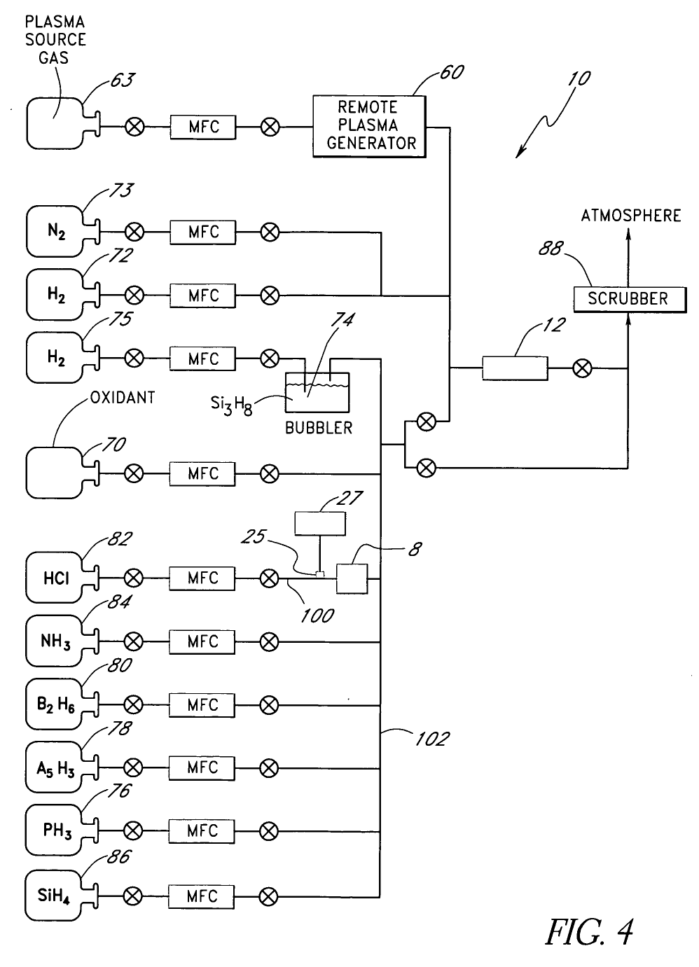

Although not illustrated, it should be appreciated that, depending upon the application, the semiconductor processing system 1 may also include additional reactant sources, conduits, various valves, flow restrictors and/or mass control devices for supplying reactant from reactant source 2 into the reaction chamber 4. For example, with respect to semiconductor manufacturing processes, the system 1 and the processing chamber 4 may be configured used for deposition (e.g., CVD). A particularly advantageous embodiment of a processing system and processing chamber, which is configured for CVD deposition will be described in more detail below with reference to FIGS. 3 and 4. Within CVD applications, the system 1 may also be used for etching and/or processes that clean portions of the reactor.

The system preferably includes a cold trap 8 that is functionally positioned between the reactant source 2 and the processing chamber 4. In the illustrated embodiment, the cold trap 8 is positioned along the reactant conduit 3, upstream of the reactant source 2 and downstream of the processing chamber 4.

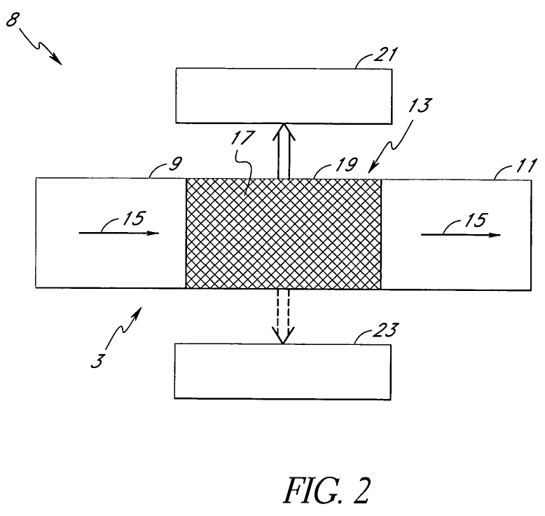

The cold trap 8 is illustrated in more detail in FIG. 2. In general, the cold trap 8 is configured to remove impurities from a reactant stream flowing through the conduit 3. As described in detail below, the impurities are removed by reducing the temperature of the impurities in the gas stream. By lowering the temperature of the impurities, the impurities are condensed into a liquid or solid form such that they can be removed from the gas stream. A trap collection area may be provided for collecting the condensed impurities.

In one particular embodiment, the reactant is a HCl gas stream, which is used in many selective epitaxial processes. As mentioned above, the best grades of HCl can have moisture concentrations in the range of 1 ppm to 30 ppm. Such concentrations of moisture can be detrimental to film growth especially in lower temperature epitaxial processes. Currently metallorganic resin purifiers are used to remove moisture from a HCl gas stream. However, such purifiers are typically limited to removing moisture only down to about 100 ppb levels in optimum conditions. In addition, if the moisture level in the HCl gas becomes higher (e.g., greater than 1 ppm) the resin purifier can quickly become overwhelmed and can no longer remove moisture to the optimum levels (e.g., 100 ppb).

With reference to FIG. 2, in the illustrated embodiment, the cold trap 8 includes an inlet 9, an outlet 11 and a cold element 13 positioned between the inlet and outlet 9, 11. The reactant gas stream 15 is configured to flow from the reactant source 2 into the inlet 9, contact the cold element 13, and then flow through the outlet 11 to the processing chamber 4.

As mentioned above, the cold trap 8 is configured to reduce the temperature of the impurities within the gas stream 15. In the illustrated embodiment, this is accomplished by providing the cold element 13 between the inlet 9 and the outlet 11. The cold element 13 may comprise any of a variety of structures or devices, which are configured to cool, preferably rapidly, one or more impurities in the gas stream 15. In the illustrated embodiment, the cold element 13 comprises a metal frit 17 positioned within a tube 19. In other embodiments the frit 17 may be formed of a different material. In other embodiments, various combinations of tubes, baffles, fins, and/or passages may also be used to form the cold element 13.

In certain embodiments, the cold element 13 is configured such that the gas stream 15 flows over and/or through portions of the cold element 13. The impurities contact the cold element 13 and are condensed to a liquid and/or solid form onto the cold element. In such embodiments, the temperature of the cold element 13 can be maintained at a temperature that is less than the condensation temperature of the impurity but greater than the condensation temperature of the gas stream.

The cold element 13 is thermally connected to a cooling device or heat sink 21 for maintaining the cold element at a reduced temperature. In any of a variety of cooling devices 21 may be used, such as, for example, various refrigeration or thermal conditioning systems.

In one embodiment, the cold trap 8 is configured to remove moisture from the gas stream. With respect to a HCl gas stream, the cold element is maintained within a temperature range from about −40° C. to about −55° C. In such an embodiment, the moisture that contacts the cold element 13 is preferably frozen onto the cold element 13.

As mentioned above, in one embodiment, the impurities are condensed and, more preferably frozen, onto the cold element 13. In such an embodiment, the cold trap 8 may be regenerated by heating (or no longer cooling) the cold element 13 and collecting the heated impurity (e.g., water) within a trap 23. The trap 23, in turn, may include a vent for selective removal of the collected impurities. In another embodiment, the cold trap 8 may be regenerated by removing the cold element 13 from the cold trap 8 and regenerating and/or replacing the cold element 13. In still another embodiment, the cold element 13 may be configured such that the impurities are collected within the trap 23 during operation of the cold trap 8. For example, if the impurities are condensed onto the cold element in a liquid form, they may be collected during operation by positioning the trap beneath the cold element 13. The element 13 can also be heated and/or purged with a gas (e.g., H₂ and/or N₂)

With respect to HCl gases, it is anticipated that the cold trap 8 can reduce moisture levels within the HCl stream to less than about 10 ppb. This represents a significant improvement over prior art resin purifiers. In addition, as compared to resin purifiers, the illustrated purifier can be regenerated very quickly using the techniques described above.

Another advantage of the illustrated embodiment will now be described with reference to FIG. 1. As described above, a drawback to prior art purifiers is that there is typically no signal indicating when the purifier becomes saturated and no longer effective. As such, the deposition process is typically compromised before any indication of saturation is determined. As described above, in one embodiment, the impurity (e.g., moisture) becomes frozen onto the cold trap 8. In embodiments, where the gas stream flows through the cold element 13, the frozen impurity reduces the cross-sectional area available to the gas stream as the frozen material builds up on the cold element 13. This results in an increase pressure drop or loss across the cold trap 8. This can be detected by sensing the upstream and/or downstream pressure of the gas stream with respect to the cold trap 8. In the illustrated embodiment, a pressure sensor 25 is positioned upstream of the cold trap 8 to sense the back pressure. As the impurities freeze onto the cold element 13, the cross-sectional area of the cold trap 8 becomes reduced resulting in an increase in back pressure. This increase can be detected and empirically or otherwise (e.g., calculated or modeled) correlated to an acceptable operating range for the cold trap 8. When the back pressure exceeds a specified limit, the cold element 13 may be regenerated as described above.

As shown in FIG. 1, the pressure sensor may be operatively connected to a control unit 27, which may include and an alarm or display portion. The control unit 27 generally comprises a general purpose computer or workstation having a general purpose processor and memory for storing a computer program that can be configured for performing the steps and functions described above for indicating when the cold trap 8 needs regeneration. In the alternative, the unit 27 can comprise a hard wired feed back control circuit, a dedicated processor or any other control device that can be constructed for performing the steps and functions described above. The alarm and/or display device portion can comprise any of a variety of visual and/or audio for conveying information gathered and/or generated by the control unit 27.

As mentioned above, in the preferred embodiments, the cold trap 8 is used within a semiconductor system. FIGS. 3 and 4 illustrate a preferred embodiment of the semiconductor system, which comprises a single-substrate, horizontal flow cold-wall reactor. However, it will be understood that certain aspects of the invention will have application to other types of reactors known in the art and that the invention is not limited to such a reactor. For examples, batch reactors can be used and advantageously allow for increased throughput due to the ability to simultaneously process a plurality of wafers. A suitable batch reactor is available commercially under the trade name A412™ from ASM International, N.V. of The Netherlands. It should also be appreciated that certain aspects of the invention will have application to other types of chemical processes within and outside the semiconductor manufacturing field.

FIG. 3 shows a chemical vapor deposition (CVD) reactor 10, including a quartz process or reaction chamber 12, constructed in accordance with a preferred embodiment. The basic configuration of the reactor 10 is available commercially under the trade name Epsilon™ from ASM America, Inc. of Phoenix, Ariz.

A plurality of radiant heat sources are supported outside the chamber 12 to provide heat energy in the chamber 12 without appreciable absorption by the quartz chamber 12 walls. The illustrated radiant heat sources comprise an upper heating assembly of elongated tube-type radiant heating elements 13a. The upper heating elements 13a are preferably disposed in spaced-apart parallel relationship and also substantially parallel with the reactant gas flow path through the underlying reaction chamber 12. A lower heating assembly comprises similar elongated tube-type radiant heating elements 14 below the reaction chamber 12, preferably oriented transverse to the upper heating elements 13a. Desirably, a portion of the radiant heat is diffusely reflected into the chamber 12 by rough specular reflector plates above and below the upper and lower lamps 13a, 14, respectively. Additionally, a plurality of spot lamps 15a supply concentrated heat to the underside of the substrate support structure (described below), to counteract a heat sink effect created by cold support structures extending through the bottom of the reaction chamber 12.

Each of the elongated tube type heating elements 13a, 14 is preferably a high intensity tungsten filament lamp having a transparent quartz envelope containing a halogen gas, such as iodine. Such lamps produce full-spectrum radiant heat energy transmitted through the walls of the reaction chamber 12 without appreciable absorption. As is known in the art of semiconductor processing equipment, the power of the various lamps 13a, 14, 15a can be controlled independently or in grouped zones in response to temperature sensors. The skilled artisan will appreciate, however, that the principles and advantages of the processes described herein can be achieved with other heating and temperature control systems.

A substrate, preferably comprising a silicon wafer 16, is shown supported within the reaction chamber 12 upon a substrate support structure 18. Note that, while the substrate of the illustrated embodiment is a single-crystal silicon wafer, it will be understood that the term “substrate” broadly refers to any surface on which a layer is to be deposited. Moreover, thin, uniform layers are often required on other substrates, including, without limitation, the deposition of optical thin films on glass or other substrates.

The illustrated support structure 18 includes a substrate holder 20, upon which the wafer 16 rests, and which is in turn supported by a support spider 22. The spider 22 is mounted to a shaft 24, which extends downwardly through a tube 26 depending from the chamber lower wall. Preferably, the tube 26 communicates with a source of purge or sweep gas which can flow during processing, inhibiting process gases from escaping to the lower section of the chamber 12.

A plurality of temperature sensors are positioned in proximity to the wafer 16. The temperature sensors can take any of a variety of forms, such as optical pyrometers or thermocouples. The number and positions of the temperature sensors are selected to promote temperature uniformity, as will be understood in light of the description below of the preferred temperature controller. In the illustrated reactor 10, the temperature sensors directly or indirectly sense the temperature of positions in proximity to the wafer.

In the illustrated embodiment, the temperature sensors comprise thermocouples, including a first or central thermocouple 28, suspended below the wafer holder 20 in any suitable fashion. The illustrated central thermocouple 28 passes through the spider 22 in proximity to the wafer holder 20. The reactor 10 further includes a plurality of secondary or peripheral thermocouples, also in proximity to the wafer 16, including a leading edge or front thermocouple 29, a trailing edge or rear thermocouple 30, and a side thermocouple (not shown). Each of the peripheral thermocouples are housed within a slip ring 32, which surrounds the substrate holder 20 and the wafer 16. Each of the central and peripheral thermocouples are connected to a temperature controller, which sets the power of the various heating elements 13, 14, 15 in response to the readings of the thermocouples.

In addition to housing the peripheral thermocouples, the slip ring 32 absorbs and emits radiant heat during high temperature processing, such that it compensates for a tendency toward greater heat loss or absorption at wafer edges, a phenomenon which is known to occur due to a greater ratio of surface area to volume in regions near such edges. By minimizing edge losses, the slip ring 32 can reduce the risk of radial temperature non-uniformities across the wafer 16. The slip ring 32 can be suspended by any suitable means. For example, the illustrated slip ring 32 rests upon elbows 34 which depend from a front chamber divider 36 and a rear chamber divider 38. The dividers 36, 38 desirably are formed of quartz. In some arrangements, the rear divider 38 can be omitted.

The illustrated reaction chamber 12 includes an inlet port 40 for the injection of reactant and carrier gases, and the wafer 16 can also be received therethrough. An outlet port 42 is on the opposite side of the chamber 12, with the wafer support structure 18 positioned between the inlet 40 and outlet 42.

An inlet component 50 is fitted to the reaction chamber 12, adapted to surround the inlet port 40, and includes a horizontally elongated slot 52 through which the wafer 16 can be inserted. A generally vertical inlet 54 receives gases from remote sources, as will be described more fully with respect to FIG. 4, and communicates such gases with the slot 52 and the inlet port 40. The inlet 54 can include gas injectors as described in U.S. Pat. No. 5,221,556, issued Hawkins et al., or as described with respect to FIGS. 21-26 in U.S. patent application Ser. No. 08/637,616, filed Apr. 25, 1996, the disclosures of which are hereby incorporated by reference. Such injectors are designed to maximize uniformity of gas flow for the single-wafer reactor.

An outlet component 56 similarly mounts to the process chamber 12 such that an exhaust opening 58 aligns with the outlet port 42 and leads to exhaust conduits 59. The conduits 59, in turn, can communicate with suitable vacuum means (not shown) for drawing process gases through the chamber 12. In the preferred embodiment, process gases are drawn through the reaction chamber 12 and a downstream scrubber 88 (FIG. 4). A pump or fan is preferably included to aid in drawing process gases through the chamber 12, and to evacuate the chamber for low pressure processing.

The preferred reactor 10 also includes a source 60 of excited species, preferably positioned upstream from the chamber 10. The excited species source 60 of the illustrated embodiment comprises a remote plasma generator, including a magnetron power generator and an applicator along a gas line 62. An exemplary remote plasma generator is available commercially under the trade name TRW-850 from Rapid Reactive Radicals Technology (R3T) GmbH of Munich, Germany. In the illustrated embodiment, microwave energy from a magnetron is coupled to a flowing gas in an applicator along a gas line 62. A source of precursor gases 63 is coupled to the gas line 62 for introduction into the excited species generator 60. The illustrated embodiment employs nitrogen gas as a precursor gas. A separate source of carrier gas 64 can also be coupled to the gas line 62, though in embodiments employing N₂ as the nitrogen source, separate carrier gas can be omitted. One or more further branch lines 65 can also be provided for additional reactants. Each gas line can be provided with a separate mass flow controller (MFC) and valves, as shown, to allow selection of relative amounts of carrier and reactant species introduced to the generator 60 and thence into the reaction chamber 12.

Wafers are preferably passed from a handling chamber (not shown), which is isolated from the surrounding environment, through the slot 52 by a pick-up device. The handling chamber and the process chamber 12 are preferably separated by a gate valve (not shown), such as a slit valve with a vertical actuator, or a valve of the type disclosed in U.S. Pat. No. 4,828,224.

The total volume capacity of a single-wafer process chamber 12 designed for processing 200 mm wafers, for example, is preferably less than about 30 liters, more preferably less than about 20 liters, and most preferably less than about 10. The illustrated chamber 12 has a capacity of about 7.5 liters. Because the illustrated chamber 12 is divided by the dividers 32, 38, wafer holder 20, ring 32, and the purge gas flowing from the tube 26, however, the effective volume through which process gases flow is around half the total volume (about 3.77 liters in the illustrated embodiment). Of course, it will be understood that the volume of the single-wafer process chamber 12 can be different, depending upon the size of the wafers for which the chamber 12 is designed to accommodate. For example, a single-wafer process chamber 12 of the illustrated type, but for 300 mm wafers, preferably has a capacity of less than about 100 liters, more preferably less than about 60 liters, and most preferably less than about 30 liters. One 300 mm wafer process chamber has a total volume of about 24 liters, with an effective processing gas capacity of about 11.83 liters. The relatively small volumes of such chambers desirably allow rapid evacuation or purging of the chamber between phases of the cyclical process described below.

FIG. 4 shows a gas line schematic, in accordance with a preferred embodiment. The reactor 10 is provided with a liquid reactant source 74 of trisilane as the preferred silicon source gas or precursor. An inert gas source 75 comprising a gas, preferably H₂, for bubbling liquid phase reactants 74 and carrying vapor phase reactants from the bubbler to the reaction chamber 12 is also shown. The bubbler holds liquid trisilane 74 as a silicon source, while a gas line serves to bubble the inert gas through the liquid silicon source and transport the precursors to the reaction chamber 12 in gaseous form.

As also shown in FIG. 4, the reactor 10 further includes a source 72 of hydrogen gas (H₂). As is known in the art, hydrogen is a useful carrier gas and purge gas because it can be provided in very high purity, due to its low boiling point, and is compatible with silicon deposition.

The preferred reactor 10 also includes a source 73 of nitrogen gas (N₂). As is known in the art, N₂ is often employed in place of H₂ as a carrier or purge gas in semiconductor fabrication. Nitrogen gas is relatively inert and compatible with many integrated materials and process flows. Other possible carrier gases include noble gases, such as helium (He) or argon (Ar).

In addition, another source 63 of nitrogen, such as diatomic nitrogen (N₂), can be provided to a remote plasma generator 60 to provide active species for reaction with deposited silicon layers in the chamber 12. An ammonia (NH₃) source 84 can additionally or alternatively be provided to serve as a volatile nitrogen source for thermal nitridation. Moreover, as is known in the art, any other suitable nitrogen source can be employed and flowed directly, or through remote plasma generator 60, into the chamber 12. In other arrangements, the gas source 63 can comprise a source of other reactant radicals for forming silicon-containing compound layers (e.g., O, C, Ge, metal, etc.).

The reactor 10 can also be provided with a source 70 of oxidizing agent or oxidant. The oxidant source 70 can comprise any of a number of known oxidants, particularly a volatile oxidant such as O₂, NO, H₂O, N₂O, HCOOH, HClO₃.

Desirably, the reactor 10 will also include other source gases such as dopant sources (e.g., the illustrated phosphine 76, arsine 78 and diborane 80 sources) and etchants for cleaning the reactor walls and other internal components (e.g., HCl source 82 or NF₃/Cl₂ (not shown) provided through the excited species generator 60). A source of silane 86 can also be provided, for deposition of a silicon layer after a first silicon layer has been deposited using a polysilane, as discussed below.

Each of the gas sources can be connected to the inlet 54 (FIG. 3) via gas lines with attendant safety and control valves, as well as mass flow controllers (“MFCs”), which are coordinated at a gas panel. Process gases are communicated to the inlet 54 (FIG. 3) in accordance with directions programmed into a central controller and distributed into the process chamber 12 through injectors. After passing through the process chamber 12, unreacted process gases and gaseous reaction by-products are exhausted to a scrubber 88 to condense environmentally dangerous fumes before exhausting to the atmosphere.

As discussed above, in addition to conventional gas sources, the preferred reactor 10 includes the excited species source 60 positioned remotely or upstream of the reaction chamber 12. The illustrated source 60 couples microwave energy to gas flowing in an applicator, where the gas includes reactants from the reactant source 63. A plasma is ignited within the applicator, and excited species are carried toward the chamber 12. Preferably, of the excited species generated by the source 60, overly reactive ionic species substantially recombine prior to entry into the chamber 12. On the other hand, N radicals can survive to enter the chamber 12 and react as appropriate.

Additionally, the plasma can be generated in situ, in the reaction chamber. Such an in situ plasma, however, may cause damage, uniformity and roughness problems with some deposited layers. Consequently, where a plasma is used, a remotely generated plasma is typically preferred.

With continued reference to FIG. 4, the reactor preferably includes a cold trap 8 as described above for purifying the gas streams from one of the gas sources 63, 73, 72, 75, 70, 82, 84, 80, 78, 76, 86. In the illustrated embodiment, the cold trap 8 is configured to purify the gas from the HCl source 82.

The cold trap 8 is positioned generally between the HCl source 82 and the reaction chamber 12. In the illustrated embodiment, the cold trap 8 is positioned in a HCl reactant line 100 downstream of the valves and mass flow controller (MFC) for the HCl source 82 and upstream of a common line 102 for other gas sources of the system 10.

HCl may be used in a variety of semiconductor processes, including, but not limited to selective deposition and cleaning of the reactor walls and/or substrates. In such processes, HCl gas is supplied to the reaction chamber 12 through the reactant line 100 and common line 102. The HCl gas stream flows through the cold 8, which reduces the temperature of the impurities (e.g., moisture) in HCl gas stream such that impurities (e.g., moisture) in the HCl gas stream are condensed and removed. The purified HCl gas stream may then be used within the reaction chamber for deposition, selective deposition and/or cleaning of the reactor walls and/or substrates.

With continued reference to FIG. 4, the illustrated embodiment comprises a pressure sensor 25 and control unit 27, which may be configured as described above to detect a pressure rise across the cold trap 8. In this manner, a signal can be generated to indicate when regeneration of the cold trap 8 is desirable or needed.

It should be noted that certain objects and advantages of the invention have been described above for the purpose of describing the invention and the advantages achieved over the prior art. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Moreover, although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. In addition, while a number of variations of the invention have been shown and described in detail, other modifications, which are within the scope of this invention, will be readily apparent to those of skill in the art based upon this disclosure. For example, it is contemplated that various combinations or sub-combinations of the specific features and aspects of the embodiments may be made and still fall within the scope of the invention. Accordingly, it should be understood that various features and aspects of the disclosed embodiments can be combined with or substituted for one another in order to form varying modes of the disclosed invention. Thus, it is intended that the scope of the present invention herein disclosed should not be limited by the particular disclosed embodiments described above, but should be determined only by a fair reading of the claims that follow.

We claim:

1. A method of forming an integrated circuit, the method comprising a
supplying a HCl gas stream to a conduit system;
cooling moisture in the HCl gas stream to remove the moisture from the HCl gas stream and produce a purified HCl gas stream; and
supplying the purified HCl gas stream to a process chamber.

2. The method of claim 1, further comprising using the purified HCl gas stream for selective deposition on a substrate positioned within the process chamber.

3. The method of claim 1, further comprising using the purified HCl gas stream for cleaning the process chamber.

4. The method of claim 1, further comprising using the purified HCl gas stream for cleaning a substrate positioned within the process chamber.

5. The method of claim 1, wherein cooling the moisture in the HCl gas stream to comprises passing the HCl gas stream over a cold element that is maintained at a temperature within a range from about −40° C. to about −55° C.

6. The method of claim 1, wherein cooling the moisture in the HCl gas stream comprises passing the HCl gas stream over a cold element.

7. The method of claim 6, further comprising condensing moisture from the HCl gas stream onto the cold element.

8. The method of claim 7, further comprising regenerating the cold element device by heating the cold element.

9. The method of claim 8, further comprising detecting pressure upstream of the cold element and initiating the regeneration of the cold element based at least in part upon the detected pressure.

10. The method of claim 6, wherein the cold element is maintained at a temperature that is less than a condensation temperature of the moisture and greater than a condensation temperature of HCl gas.

11. An apparatus for forming a semiconductor device, the apparatus comprising:
a source of HCl gas;
a gas conduit system that connects the source of HCl gas to the reaction chamber; and
a purifier positioned within the gas conduit system for purifying an HCl gas stream, the purifier configured to reduce the temperature of impurities in the HCl gas stream flowing through the purifier.

12. The apparatus as in claim 11, wherein the purifier includes a cold element configured to contact the impurities in the HCl gas stream.

13. The apparatus as in claim 12, wherein the cold element comprises a metallic frit.

14. The apparatus as in claim 12, wherein the cold element is configured such that the impurities condense onto the cold element.

15. The apparatus as in claim 14, wherein the purifier includes trap for collecting impurities condensed onto the cold element.

16. The apparatus as in claim 12, comprising a pressure sensor positioned upstream of the cold element.

17. The apparatus as in claim 12, comprising a control system configured to generate a signal, based at least in part upon the signal from the pressure sensor, indicating that the cold element needs to be regenerated.
